(19) United States
(12) Patent Application Publication
(10) Pub. No.: US 2023/0017565 A1
(43) Pub. Date: Jan. 19, 2023

(54) METHOD OF READING A MULTI-LEVEL RRAM

(71) Applicant: COMMISSARIAT A L'ENERGIE ATOMIQUE ET AUX ENERGIES AL TERNATIVES, Paris (FR)

(72) Inventors: Gabriel MOLAS, Grenoble Cedex 09 (FR); Joel MINGUET LOPEZ, Grenoble Cedex 09 (FR); François RUMMENS, Grenoble Cedex 09 (FR); Elisa VIANELLO, Grenoble Cedex 09 (FR)

(73) Assignee: COMMISSARIAT A L'ENERGIE ATOMIQUE ET AUX ENERGIES ALTERNATIVES, Paris (FR)

(21) Appl. No.: 17/811,341

(22) Filed: Jul. 8, 2022

(30) Foreign Application Priority Data
Jul. 12, 2021 (FR) 21 07535

(51) Int. Cl. G11C 13/00

(52) U.S. Cl. CPC G11C 13/0069; G11C 13/004; G11C 13/0038

(57) ABSTRACT

Circuit and method for controlling a resistive memory formed by resistive memory cells each provided with a resistive memory element associated in series with a selector, each cell implementing a coding referred to as “multi-level” coding and being programmed in a given programming state among k (with k>2) possible programming states, wherein during a read operation, a sequence of different read voltages are applied to the given cell, and at each applied read voltage it is detected whether the read current passing through said given cell consecutively to the application of said read voltage corresponds to a leakage current level of the selector when this selector is in an off state or to a current level when the selector is in an on state.

### TECHNICAL FIELD

The present application relates to the field of non-volatile memories and more precisely to that of resistive memories provided with so-called “multi-level” cells which can adopt a number of programming states higher than two to allow more than two distinct levels to be encoded per cell and in particular more than one bit per cell. It relates more precisely to a control method and a control circuit for reading and programming such resistive memory cells.

### PRIOR ART

Among non-volatile memories, resistive memories have the advantage of high operating speed, low electrical power consumption and a long service life.

The resistive memories are formed by a set of cells each provided with at least one resistive element of variable resistivity. Each resistive element includes a material capable of reversibly switching between at least one state referred to as a High-Resistance State (HRS) and at least one other state referred to as Low-Resistance State (IRS). The mechanism at the origin of the variation in resistance of the memory cell depends on the technology used. There are several resistive memory technologies including in particular Phase-Change Random-Access Memories (PCRAM), Conductive-Bridging Random Access Memories (CBRAM) and Oxide-based Random Access Memories (OxRAM).

A resistive memory cell with a resistive element and programmable to have one out of two possible distinct resistance states LRS or HRS and is only capable of storing one bit of data.

Recently, resistive memory cells each provided with a programmable resistive element between more than two distinct levels have appeared. Such cells can thus make it possible to store multiple bits of data.

The document “High-Density 3D Monolithically Integrated Multiple 1T-1R Multi-Level-Cell for Neural Networks”, by Esmanhotto et al. 2020 IEEE international Electron Devices Meeting (IEDM) presents for example a type of cell memory, integrated into a matrix and allowing the use of nine distinct conductance levels, and permitting the use of nine distinct levels of conductance, in order to implement Multi Level Coding (MLC), The memory cell is here of the 1T-1R type, i.e. formed by a resistive element associated with an access transistor which alternately blocks access or allows access to the resistive memory element for reading or writing or erasing or programming operations while limiting undesirable leakage currents in the rest of the matrix.

With such a structure, a low voltage reading, for example in the order of 100 mV, is possible and allows a distinction to be made between different levels of current flowing through the resistive element and corresponding to different possible states stored in the cell memory.

However, the 1T-1R cell memories, due to their access transistor are problematic in terms of their space requirement.

1S-1R type cells in which the transistor is replaced by a selector formed by a switch of two terminals have a reduced space requirement. FIG. 1 shows an equivalent circuit diagram of such a 15-1R cell. The selector S typically functions as at least one diode or as two diodes mounted hi an antiparallel or head-to-tail arrangement. The selector S is formed by a stack of layers generally formed in a BEOL (Back End Of Line) part of microelectronic device. This part in which the resistive elements are also formed is typically also dedicated to interconnections.

FIGS. 2A-2B, by means of voltage-current characteristics, are used to illustrate different parameters of a read operation of a 1S-1R cell that may be programmed on one of three possible distinct programming states.

When reading the 1S-1R cell if the read current is higher than the programming currents Iprog1, Iprog2, Iprog3 (FIG. 2A), the memory is at risk of being programmed at this read current. It is then considered to be over-programmed.

In a different case, where the read current is lower than the programming currents (FIG. 2B), it is then difficult to establish a distinction of the level stored out of the different levels at which the memory can be programmed. The same current is read in all cases, regardless of the state of resistivity at which the programmed resistive element is found.

The problem consists of reading a programming state of a RRAM memory cell programmed according to multi-level coding.

### PRESENTATION OF THE INVENTION

Thus, according to one aspect, the present invention relates to a memory device formed by resistive memory cells each provided with a resistive memory element associated in series with a selector, each cell implementing coding referred to as “multi-level” coding and being programmed to a given programming state among k with k>2 possible programming states,
the device comprising a read circuit configured to apply, during a read operation in a given cell: a sequence of at least two successive and different read voltages to the given cell.

The applied read voltages are selected as a function of the programming states that the memory cell can take on.

The read circuit can be configured such that said sequence comprises the application of a first read voltage to the given cell, the first read voltage belonging to a first range of voltages between a first threshold voltage and a second threshold voltage, and being selected from a set of read voltages of a sequence of different read voltages to which a cell of said memory is likely to be subjected during said read operation, then applying a second read voltage, of said sequence of read voltages, the second read voltage being different from the first read voltage and belonging to a second range of voltages between the second threshold voltage and a third threshold voltage, the given programming state being determined as a function of respective values of a first read current flowing through said given cell resulting from the application of said first read voltage and a second read current passing through said given cell consecutive to the application of said second read voltage.

The read circuit can be configured to detect at each applied read voltage of said sequence if a read current passing through said given cell and resulting from the application of said read voltage corresponds to a first leakage current level of the selector when this selector is in an off state or if the read current corresponds to a second current level when the selector is in an on state.

Advantageously, the read voltage at which the selector turns on is related to the programming state of the memory.

Advantageously, during the read operation the sequence of different read voltages is applied to said given memory cell according to an increasing order of read voltages or according to a decreasing order of read voltages.

Advantageously, the selector can be a switch with two terminals, in particular of the oval threshold switch type (OTS).

Advantageously, the resistive memory element is an oxide-based resistive memory element (OxRAM).

According to a particular embodiment, the read circuit can be provided with an amplifier having a non-inverting input to which the read voltage is applied and an inverting input connected to the drain of a common drain transistor coupled to the output of the selector.

According to a particular implementation of the device, the read circuit can be configured to compare an image current from a first current mirror receiving a current from the selector with another current from a second current mirror to which a reference current is applied.

According to a particular embodiment, the read circuit can be provided with a comparator for comparing a voltage at the output of the amplifier with a reference voltage.

According to a particular embodiment, the read circuit can be provided with an integration capacity charged with an image current of a current from the selector, the read circuit being configured to discharge the integration capacity during the read operation according to said sequence of voltages following the application of a first read voltage of said sequence and prior to the application of a second read voltage following said first read voltage in said sequence of voltages.

According to one aspect, the present invention provides a method for controlling a resistive memory formed by resistive memory cells each provided with a resistive memory element associated in series with a selector, each cell implementing a so-called “multi-level” coding and being programmed in a given programming state among k (with k>2) possible resistive states, the method comprising, during a read operation of a given programming state stored in a given cell (3i) among said cells resistive memories, steps consisting of:
applying a first read voltage to the given cell, the first read voltage belonging to a first range of voltages between a first threshold voltage and a second threshold voltage, and being selected from a set of read voltages of a sequence different read voltages to which a cell of said memory is likely to be subjected during said read operation, then
applying a second read voltage, of said sequence read voltages, the second read voltage being different from the first read voltage and belonging to a second range of voltages between the second threshold voltage and a third threshold voltage, the given programming state being determined as a function of respective values of a first read current traversing said given cell consecutively to the application of said first read voltage and a second read current traversing said given cell consecutively to the application of said first read voltage,
   or,
triggering the end of the read operation:
when the first read voltage is the highest voltage of said sequence of voltages and the first current flowing though said given cell and consecutive to the application of said first read voltage corresponds to a leakage current level of the selector when this selector is in an off state, or
when the first read voltage is the lowest voltage of said sequence of voltages and the first current corresponds to a current level when the selector is in an on state.

Advantageously, the read operation further comprises, after the application of the second read voltage:
a step of determining said given programming state as a function of the value of a sum between said first read current and said second read current.

According to one possible implementation, after the application of the first read voltage and prior to the application of the second read voltage or on triggering the end of the read operation, the method can comprise:
a binary detection step consisting of determining whether the first read current corresponds to a leakage current level of the selector when this selector is in an off state or the first current corresponds to a current level when the selector is in an on state, in particular by comparing the first read current or an image of the first read current in the form of a voltage or a current at a given threshold.

According to one embodiment, the read operation can further comprise, after the step consisting of applying the second read voltage:
applying a third read voltage, of said sequence of read voltages, the third read voltage being different from said first read voltage and second read voltage and belonging to a third range of voltages between the third threshold voltage and a fourth threshold voltage, or
triggering the end of the read operation:
when the second read voltage is, apart from the first read voltage, the highest voltage of said voltage sequence and the second read current corresponds to a leakage current level of the selector when this selector is in an off state, or
when the second read voltage is, apart from the first read voltage, the lowest voltage of said sequence of voltages and the second read current corresponds to a current level of the selector when the selector is in an on state.

The read operation can further comprise, after applying the third read voltage:
a step of determining said given programming state as a function of the value of a sum between said first read current, said second read current, and a third current passing through said given cell consecutive to the application of said third read voltage.

Advantageously, the method can further comprise, after applying the second read voltage and prior to the application of the third read voltage or triggering the end of the read operation, a binary detection step consisting of determining whether the second read current corresponds to a leakage current level of the selector when this selector is in an off state or if the second current corresponds to a current level when the selector is in an on state.

According to one advantageous mode, prior to the read operation the method comprises a step consisting of programming the given state performed by applying a succession of current pulses to the given cell.

### BRIEF DESCRIPTION OF THE DRAWINGS

The present invention is explained further on the basis of the following description and the accompanying drawings in which:

FIG. 1 shows an equivalent electrical diagram of a conventional 1S-1r type resistive memory cell RRAM;

FIGS. 2A, 2B illustrate the constraints of reading different levels of read current in a “multi-level” memory cell allowing coding on more than two levels°;

FIG. 3 illustrates a RRAM 3D memory provided with multi-level memory cells;

FIG. 4 illustrates a RRAM memory provided with multi-level memory cells and having a “cross-bar” arrangement;

FIG. 5 illustrates the read current-read voltage characteristics during read operations conducted on a multi-level RRAM memory cell and likely to be in a one of three possible distinct resistive states;

FIG. 6 illustrates a read operation of a multi-level memory cell during which a sequence of increasing read voltages is applied in order to determine the programming state to which this cell is programmed;

FIG. 7 illustrates a read operation of a multi-level memory cell during which a sequence of decreasing read voltages is applied in order to determine the programming state to which this cell is programmed;

FIG. 8 illustrates a read operation performed on a multi-level RRAM memory cell and able to be in one of four possible distinct programming states;

FIG. 9 illustrates a first example of a read circuit of a 1S-1R type RRAM cell;

FIG. 10 illustrates a second example of a read circuit of a 1S-1R type RRAM cell;

FIG. 11 illustrates a third example of a read circuit of a 1S-1R type RRAM cell;

FIG. 12 illustrates a fourth example of read circuit of a 1S-1R type RRAM cell;

FIGS. 13A, 13B illustrate a first method of programming a multi-level and 1S-1R type RRAM cell;

FIGS. 14A, 14B illustrate a second method of programming a multi-level and 1S-1R type RRAM cell;

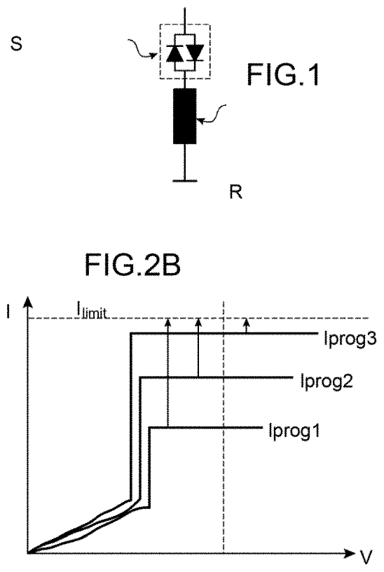

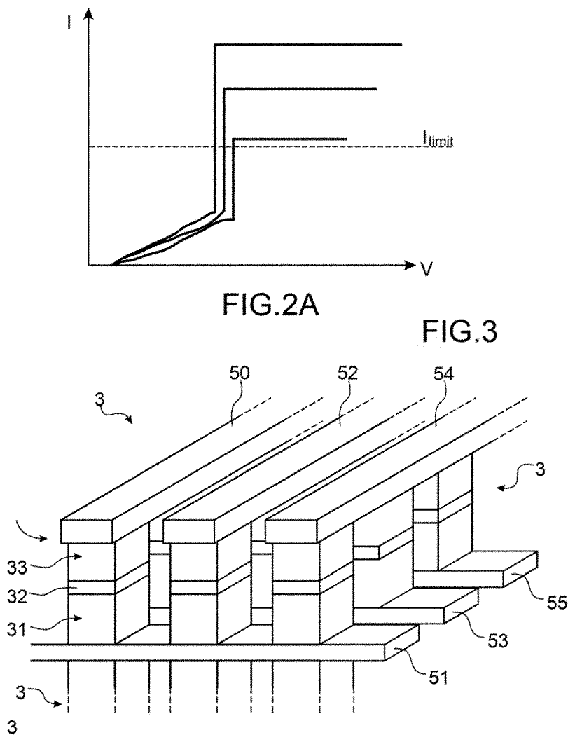

Identical, similar or equivalent parts of the different figures have the same reference numerals so as to facilitate the transition from one figure to the other.

The different parts represented in the figures are not necessarily depicted to a uniform scale to make the figures more readable.

### DETAILED PRESENTATION OF PARTICULAR EMBODIMENTS

FIG. 3 shows a perspective view of a resistive memory 1.

The memory 1 here has the special feature of being formed by a plurality of multi-level memory cells 3 (MLC) each making it possible to store more than one bit per cell. Thus, instead of two single resistive states “high” and “low” (HRS and LRS respectively) each corresponding to a programming state, the cells 3 can be set here to a given “programming” state among more than two distinct programming states. Then at least one intermediate resistive state is defined between the LRS resistive state and the HRS resistive state.

Each cell 3 of the memory 1 is interposed here between: a first conductive element 50, 52, 54; and a second conductive element 51, 53, SS. The conductive elements 50, 51, 52, 53, 54 and SS are, in the illustrated example, arranged such that they form a matrix, each intersection of which corresponds to a location of a memory cell. The memory 1 has in this particular embodiment a three-dimensional structure. However, a reading method according to the invention can be applied to other types of memory arrangements 1.

Each memory cell 3 includes a stack, defining an electrical connection in series: of a resistive memory element 31 and a selector 33. The conductive elements 50, 51, 52, 53, 54 and 55 make it possible to address the memory cells 3 of the memory 1, each memory cell 3 being connected to its own pair of conductive elements.

To read or write (in other words program) the resistive memory element 31, the relevant memory cell 3 is selected. The selection is performed, for example by applying a potential difference between the pair of conductive elements specific to the memory cell 3 considered. This difference in potential is capable of modifying the state of the selector 33, so that an electric current can flow in the memory cell 3 considered. Once the read or write operation has been completed, a potential difference is no longer applied between the two conductive elements forming the pair of conductive elements of the memory cell 3 concerned.

The memory concerned can be a Conductive Bridging Random Access Memory (CBRAM), or according to a preferred variant, an Oxide-based Resistive Memory (OxRAM). The resistive memory element 31 can in this case be formed by a stack of an oxide layer, for example a layer of hafnium dioxide (HfO₂) and a metal layer, for example a layer of titanium (Ti). A particular embodiment provides a stack of a layer of HfO₂ with a thickness of between 5 nm and 10 nm, for example in the order of 10 nm, and a layer of Ti with a thickness of between 5 nm and 10 nm, for example 10 nm. The resistive memory element 31 can be further interposed between a pair of electrodes, for example based on TiN.

The selector 33 is a two-terminal switch forming at least one diode or two head-to-tail diodes. This selector 33 can be in particular an Ovonic. Threshold Switch (OTS), for example made of chalcogenide material(s). A particular embodiment provides an OTS switch formed by a layer based on GeSeSbN (also referred to as GSSN) with a thickness of between 5 nm and 25 nm, for example in the order of 10 nm.

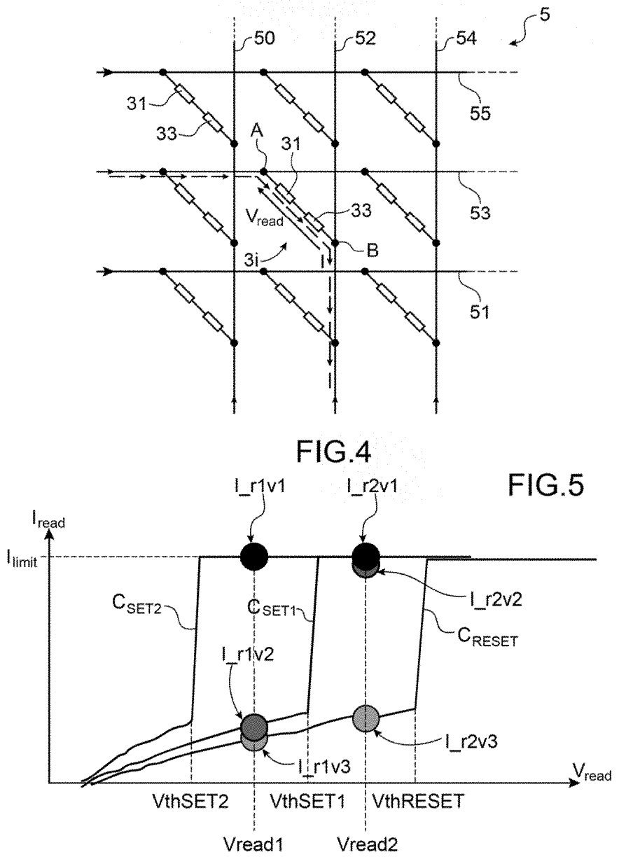

FIG. 4 shows, in schematic form, an embodiment of a bidirectional matrix 5 of 1S-1R type memory cells each formed by a memory element 31 and a selector 33, and according to a “cross-bar” type arrangement.

Assuming that it is necessary to read a programming state of a given memory cell 3i of the matrix 5, a voltage, denoted Vread, is applied here between the conductive elements 52 and 53 connected on either side of the memory point 3. At the same time, all other conductive elements 50, 51, 54 and 55 are typically maintained at a potential in the order of zero volts. Thus, a potential difference is imposed between points A and B, where the memory cell 3i contacts the conductive elements 53 and 52 respectively, which is approximately equal to the read voltage Vread, to drops in voltage in the conductors.

As the cells here are multi-level cells MLC, programmed to more than two distinct states, a particular read operation is implemented.

The reading here is likely to be performed in several successive sub-steps, each of which may comprises the application of a read voltage and the detection of a read current, with different levels of read voltages from one sub-step to the next.

An example of a read operation of a resistive memory cell of a memory whose cells have each been previously programmed to one of three possible given distinct programming states will now be described in connection with FIG. 5.

These programming states are likely to be obtained through two distinct levels of programming currents, ISET1, and ISET2. For example, ISET1 can be expected to be in the order of 100 μA, and ISET2 in the order of 200 μA.

The control of the ISET programming current can be achieved through transistors located at the end of a row and/or column of a matrix arrangement. Typically, one transistor per row and one dedicated programming transistor per column can be provided in the matrix arrangement. By adjusting the gate voltage of this dedicated transistor, the current can be controlled which will flow and thus program a memory cell during a write operation. Regardless of the ISET programming current value, a programming voltage is typically applied across the cell that is generally greater than the threshold voltage VthRESET, i.e. the threshold voltage of the cell 1S1R that is in the erased state.

To perform a read operation on a memory cell, firstly a first read voltage denoted Vread1 is applied.

This first read voltage Vread1 is equal to a value included in a first voltage range, defined here between a first cell threshold voltage, denoted VthSET2 and a second cell threshold voltage denoted VthSET1 with Vread distinct from VthSET1 and VthSET2. Then the value of a read current Iread1 flowing in the cell memory is measured.

The memory is programmed at a given ISET current. This programming state fixed by the programming current determines the threshold voltage of the 1S1R structure above which it switches and becomes conductive. The more this structure is programmed at high current, the lower the threshold voltage. Thus, if programming is at ISET1=100 μA, there would be a threshold voltage Vth1 at which the cell 1SR switches, whereas if programming is at ISET2=200 μA there would be threshold voltage Vth , such that Vth2<Vth1.

If, in a first case, the resistive element of the cell is programmed to the first programming state, its selector turned on and the first current value measured (point I_r1v1 on the CSET2 curve) corresponds to a current Ilimit. The current Ilimit is a current flowing through the cell when its selector is on and which can be for example in the order of several tens or hundreds of micro-amperes, for example in the order of 100 μA.

The current Ilimit is a current limiting the conduction of the 1S1R cell during reading. Regardless of the level at which the memory is programmed (high or low Iprog current), the same Ilimit current is read here when the cell switches. This current Ilimit can be controlled by the dedicated transistor at the end of the line or column by controlling the voltage applied to the gate of this transistor.

In a second case, where the resistive element 31 is programmed to a second programming state, here obtained by means of an intermediate programming current at a lower level than that of the programming current corresponding to the first programming state, the selector 33 is kept off and the first current value measured (points I_r1v2 on the CSET1 curve) corresponds this time to a leakage current Ioff_OTS of the selector 33. The detection of a current level Ioff_OTS or Ilimit can be performed by detecting that at least one threshold has been exceeded as will be described below.

In a third case where the resistive element 31 is in a third programming state, corresponding to a programming current level lower than that of the first and second programming state, the selector 33 is kept off and the first measured current value (point I_r1v3 on the CRESET curve) corresponds to the leakage current Ioff_OTS of the selector 33.

Then, according to a second sub-step of the read operation, a second read voltage denoted Vread2 is applied to the same cell that is to be read and in this example is higher than the first read voltage Vread1.

This second read voltage Vread2 is provided in a second voltage range, different from the first voltage range and this time between the second threshold voltage VthSET1 and a third threshold voltage, denoted VthRESET.

Then the value of a current circulating in the memory cell is measured. By applying the voltage Vread2, a second read current value Iread2 is measured.

In a case where the resistive element 31 is in the first programming state, the selector 33 is turned on and the second current value measured corresponds (point I_r2v1 on the CSET1 curve) to the current Ilimit.

In another case where the resistive element 31 is in the second programming state, the selector 33 is turned on and the second measured current value (point I_r2v2 on the CSET2 curve) corresponds to the Ilimit current.

In a third case where the resistive element 31 is in the third programming state, the selector is kept off and the second measured current value (point I_r2v3 on the CRESET curve) corresponds to a leakage current IoffOTS of the selector 33.

The current values read in each of the sub-steps in which distinct read voltages are applied can then be added together.

In the case described above where two successive readings are performed with two distinct read voltages, the first current value Iread1 read consecutively to the application of the first read voltage vread1 and the second current value Iread2 read consecutively to the application of the second read voltage vread2 are added up.

The table below lists the results of a read operation comprising two successive read sub-steps “Read1” and “Read2” of a given cell consecutively to the application of a first read voltage Vread1 then a second read voltage Vread2 respectively, in a theoretical case where Ilimit=100 μA and where the leakage current. IffOTS is 0 μA.

The sum Iread1+Iread2 of the first value of the current resulting from the application of the first voltage and of the second value of the current resulting from the application of the second voltage, makes it possible here to distinguish precisely 3 distinct levels of current each corresponding to one of the 3 programming states to which the cell is likely to be programmed.

TABLE 1

| | Read1 | Read2 | Somme |
|---|---|---|---|
| SET2 | 100 μA | 100 μA | 200 μA |
| SET200 μA | | | |
| SET1 | 0 μA | 100 μA | 100 μA |
| SET100 μA | | | |
| RESET | 0 μA | 0 μA | 0 μA |

Thus, when Iread1+Iread2=2*IffOTS, this means that the read memory cell is in the third programming state, obtained by the highest programming current ISET2.

When Iread1+Iread2=Ilimit=IoffOTS, this means that the read memory cell is in the second programming state, obtained by an intermediate programming current ISET1.

When Iread1+Iread2=2*Ilimit, this means that the read memory cell is in the first programming state.

At each of the current reading sub-steps Iread1 then Iread2, either a Ilimit current or a IoffOTS current is read here, the respective values of which can be easily distinguished from each other and which are not very dependent on the variabilities of the memory read.

In particular, in the case where the selector 33 is of the OTS type, the current Ilimit is preferably chosen such that Ilimit>Ihold-OTS with Ihold-OTS the holding current of the OTS below which it remains in the off state.

The Ilimit current is set preferably lower than the weakest programming currents ISET1, ISET2 used, for example if programming at different current levels 100 μA, . . . , k*100 μA (with k an integer such as k>1), a Ilimit such as Ilimit<100 μA is provided.

The leakage current IoffOTS of the selector 33 can be adjusted. In the case for example where the selector 33 is of the OTS type made from a GSSN material, the thickness of this material GSSN can be adjusted according to the desired leakage current. By reducing the thickness of the GSSN material, the value of the leakage current IoffOTS increases. The different threshold voltages VthSET1, VthSET2, VthRESET depend in particular on the respective compositions of the resistive element 31 and the selector 33, for example of the OTS type. Preferably, the stacks on which the resistive element 31 and the selector 33 are formed so as to have large VthSET1-VthSET2 and VthRESET-VthSET1 switching threshold differences and for example greater than 100 mV, preferably at least 500 mV and advantageously in the order of 1V.

An example of a memory cell with an OTS selector made of 5 nm thick GSSN and an OxRAM-type memory element, in particular formed by a stack of HfO₂ and Ti and with a critical dimension of the active zone active in the order of 80 nm, a threshold voltage Vth VthOTS+0.2 V (VthOTS being the threshold for switching to an on state of the selector) can be provided for a cell programmed to a state corresponding to a resistance for example of 1 kΩ. For a cell programmed to a state corresponding to a resistance for example of 10 kΩ, it can be Vth=VthOTS+0.7 V, while for a cell programmed to a state corresponding to a resistance of for example 10 KΩ, it can be Vth=VthOTS+2.4V.

The reading method described above is not limited however to reading cells programmed to one of three distinct programming states and applies to reading cells for which the number of resistive programming states is greater than three. The number of programming states that can be coded on a single cell is typically limited and provided to be less than a given limit, for example 15 or 10 or advantageously 4 making it possible to maintain a sufficient difference ΔVth of the switching voltages.

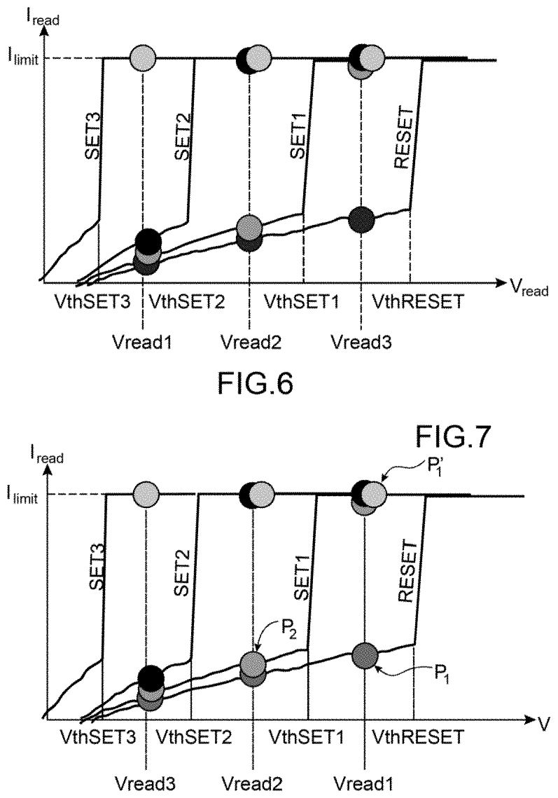

In another embodiment illustrated in FIG. 6, the read operation is likely to include this time three successive current read sub-steps in order to distinguish a level of programming between four distinct programming states likely to be stored in a RRAM memory cell that needs to be read.

In this example, a sequence of read voltages Vread1, Vread2, Vread3 is applied in an ascending order of read voltage levels.

A first read voltage Vread1 is thus applied first to a cell, between a threshold voltage VthSET3 and another threshold voltage VthSET2 (in particular VthSET3<Vread1<VthSET2) and a first current value Iread1 resulting from the application of this first read voltage Vread1 is acquired.

Then, a second read voltage Vread2 is applied, higher than the first read voltage Vread1 and is between a threshold voltage VthSET2 and another threshold voltage VthSET1 (in particular VthSET2<Vread2<VthSET1) and a second current value Iread2 is acquired from the application of this second read voltage Vread2.

A third read voltage Vread3, higher than the second read voltage Vread2, is applied and is between a threshold voltage VthSET1 and another threshold voltage VthRESET (in particular VthSET1<Vread3<VthRESET) and a third read current value Iread3 is acquired resulting from the application of this third read voltage Vread2.

Then the first current value Iread1, the second current value Iread2 and the third current value Iread3 are added together.

As a function of the value of the sum Iread1+Iread2+Iread3 obtained, a given programming state is associated with the read memory cell from among the four programming states to which this cell can be programmed.

The table below lists the possible results of such a read operation with three successive reading sub-steps “Read1”, “Read2”, “Read3” of current flowing through a cell following the respective application of a first read voltage then a second read voltage, then a third read voltage in a theoretical case where Ilimit=100 μA and where IffOTS=0 μA.

The sum obtained here makes it possible to distinguish in a precise manner 4 current levels each corresponding one of the 4 programming states to which the resistive cell can be programmed.

TABLE 2

| | Read1 | Read2 | Read3 | Somme |
|---|---|---|---|---|
| SET300 μA | 100 μA | 100 μA | 100 μA | 300 μA |
| SET200 μA | 0 μA | 100 μA | 100 μA | 200 μA |
| SET100 μA | 0 μA | 0 μA | 100 μA | 100 μA |
| RESET | 0 μA | 0 μA | 0 μA | 0 μA |

In any of the examples described above, a succession of read voltages is applied in increasing order of voltage.

However, a different sequence of read voltages can be provided to implement the read operation.

Thus, in particular it is possible to apply distinct and decreasing read voltages in succession.

In either of the above examples of read operation, a read current is read in each sub-step when a new read voltage is applied, and each time the level of the read current is determined and/or whether it corresponds to that of an off state of the selector or an on state of the selector.

Then, from this determination of each current the state is evaluated in which the memory element has been programmed. Thus, for example a sum of all of the read currents is made in order to determine the programming state of the cell subjected to the read operation.

According to one embodiment variant, in some cases, the state of a cell programmed according to a multi-level coding can be determined before the complete read voltage sequence has been applied.

This is the case in particular when a decreasing order of application of the read voltages Vread is followed.

Thus, it may be started by applying the highest read voltage. Referring to the example described above, firstly the voltage Vread1 is applied such that VthSET1<Vread3<VthRESET in order to obtain a current value.

This current value is then read.

In the case (point P1 in FIG. 7) where the current read corresponds to a leakage current level of the selector IoffOTS and the current read is thus lower than a given threshold, corresponding for example to a given leakage current value, it is possible to trigger the stop of the reading.

Indeed, in this case, the current value read corresponds to the highest programming state among the programming states to which the memory cell can be programmed. The current value read at the voltage Vread1 can then be directly associated with the programming state corresponding to the highest programming current level. The reading can then be stopped.

In another case (points P′1 in FIG. 7) where the current level read consecutively to the application of the first read voltage Vread1 is higher than the given threshold, the reading can be continued.

A second read voltage V_{read2} is then applied to the memory cell 3, this time lower than the previous one and belonging to a lower voltage range than the first read voltage V_{read1}. In this example, V_{read2} is such that VthSET2<V_{read2}<VthSET1.

In the case where the current level read consecutively to the application of the second voltage Vread2 corresponds that of a leakage current IoffOTS of the selector (point P2 in FIG. 7), and the current read is in particular lower than the given current threshold I_{SHRS}, the read operation can be stopped.

It is then possible to directly associate the current value read at voltage Vread2 with a second programming state corresponding to the second highest programming current level after the highest one.

More generally, when a decreasing sequence of read voltage is followed, once the current read is below the given current threshold, the reading can be stopped, thus making it possible to reduce the processing time for performing a read operation.

The table below lists the possible results of a read operation of the type described above on a memory cell programmed to a given programming state among four distinct programming states, SET300 μA, SET100 μA, SET200 μA, RESET in a theoretical case where Ilimit=100 μA and where IffOTS=0 μA.

TABLE 3

| | Read1 | Read2 | Read3 | Somme |
|---|---|---|---|---|
| SET300 μA | 100 μA | 100 μA | 100 μA | 300 μA |
| SET200 μA | 100 μA | 100 μA | 0 μA | 200 μA |
| SET100 μA | 100 μA | 0 μA | NA | 100 μA |
| RESET | 0 μA | NA | NA | 0 μA |

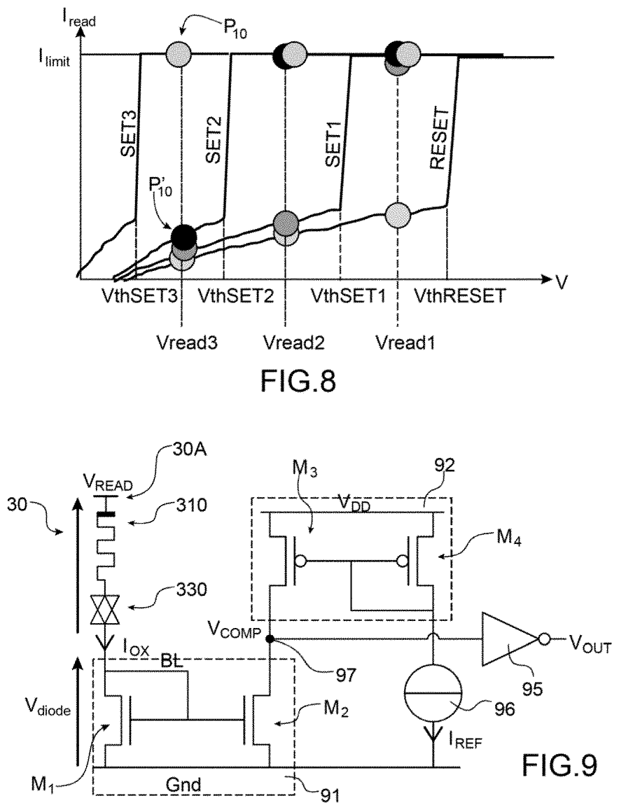

Alternatively, as illustrated in the voltage-current characteristic of FIG. 8, when following an increasing order of application of read voltages, it may also be possible in some cases, to determine the programming state of a cell programmed according to multi-level coding, before having performed the total sum of the read currents or before having applied a complete sequence of read voltages. Thus, it is possible to start by applying the lowest read voltage first. First of all a first voltage Vread1 is applied such that VthSET3<Vread1<VthSET2 in order to obtain a current value.

This current value is then read.

In the case (point P10 in FIG. 8) where the read current corresponds to the limit current when the selector is on, the reading can be stopped.

The current value read can then be directly associated with the voltage Vread1 at a programming state corresponding to the lowest programming current level.

In other cases (points P′10 in FIG. 8) where the current level read consecutively to the application of the first read voltage vread1 corresponds to that of leakage current IoffOTS the reading can be continued.

Thus, when an increasing sequence of read voltages is followed, with Vread1<Vread2<Vread3, as soon as the current read is higher than the given threshold, the reading can be stopped, which also makes it possible to achieve a gain in processing time and at the same time to limit consumption.

Such a way of performing the read operation can make it possible to dispense with a specific portion of circuitry intended to vary out a current sum and/or to avoid having to necessarily carry out an analogue-to-digital conversion of the sum of currents.

Alternatively, examples of the sequence of application of increasing or decreasing read voltages can include a dichotomous type sequence, in particular when a large number of distinct read voltages are applied sequentially.

A determination of the read current flowing through the cell consecutively to the application of a read voltage Vread and a binary detection allowing a distinction to he made between a current level Ilimit corresponding to the current when the selector and the storage element are conducting and a current level corresponding to the leakage current IoffOTS when the selector is off can be carried out for example with the aid of a read circuit as illustrated in FIG. 9.

The read circuit applies here to a multi-level 1S-1R type cell in particular with a resistive storage element 310 having an OxRAM type structure in series with an OTS type selector 330.

The read current denoted Iox is compared to a threshold in the form of a reference current Iref produced by a generator 96, with Iref for example in the order of 1 nA. As a function of the value of the current Iox flowing through the cell 30, a potential Vcomp of a node 97 coupled to an input of an inverter 95 varies. The node 97 is arranged between a first transistor stage 91 and a second transistor stage 92, The first stage 91 receives the current Iox and is formed by transistors M1, M2 mirroring the current, whereas the second stage 92 with transistors M3, M4 is also mirrored in current and is connected to the generator 96. The image of the current Iox entering into the first stage is compared with the reference current Iref. The output of the inverter 95 produces a binary signal V_{OUT} the state of which differs depending on whether the read current Iox is at a level corresponding to Ilimit, or Iox is at a level corresponding to IoffOTS.

To apply different read voltages, the read voltage is modulated by varying a potentiel applied to a coupled conductive element suitable for coupling to a first end 30A of the cell 30.

For example, there can be a current Iox passing through the cell in the order of 10 μA when the selector is on (ON) and in the order of 100 nA when the selector is in an off state (OFF). A voltage Vdiode of transistor M₁ is able to vary in the order of 200 mV between such current levels. This voltage Vdiode is preferably taken into account when reducing the voltage difference between two successive read voltages Vread1 and Vread2 of different levels, preferably providing |Vread1−Vread2|>200 mV.

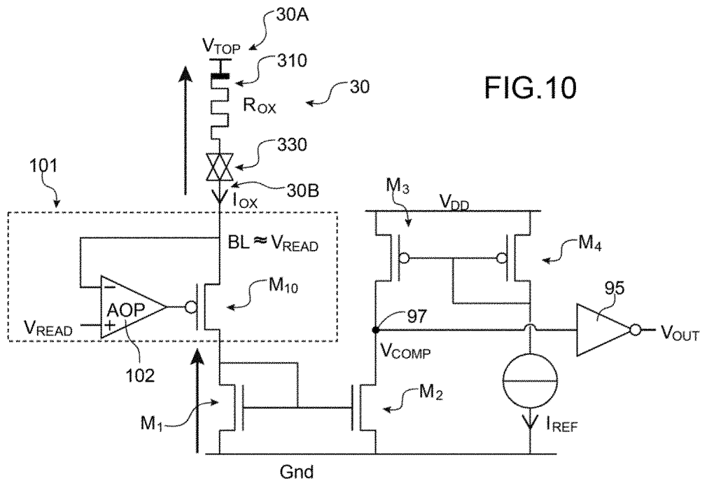

A variant of the read circuit illustrated in FIG. 10 provides for the further introduction of a stage 101 forming a voltage regulating loop at the output of the cell 30, between the latter and the first transistor stage M1, M2. The regulation loop is formed here by means of an amplifier 102 whose non-inverting input receives the read voltage Vread that can be modulated and the inverting input of which is coupled to a conducting element, typically a bit line BL connected to a second end 30B of the cell 30 and receiving the current Iox. The output of the amplifier 102 is coupled to the gate of a transistor M10, here of the PMOS type. The transistor M10 is mounted here in common drain and does not influence the gain of the amplification stage. The drain potential of the transistor M10 is modulated without modifying the value of the current in the branch.

Such an arrangement facilitates the application of distinct read voltages, the read voltage being applied this time to a second end 30B of the cell 30 opposite the first 30A to which it is applied in the preceding embodiment. The first end 30A is set this time to a fixed potential V_{TOP}.

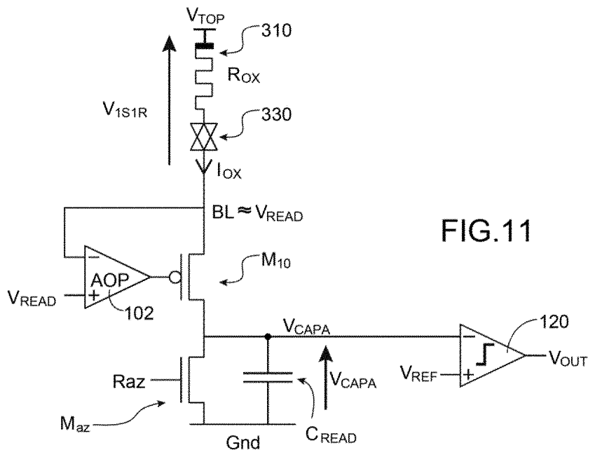

Another variant of the read circuit, illustrated in FIG. 11, uses the voltage regulation stage 101 of the previously described embodiment. The current Iox passing through the cell 30 is here integrated by charging a read capacitor Cread, itself coupled to a voltage comparator 120 producing a binary output signal Vout. A voltage Vcapa across the capacitor Cread is the image of the current passing through the cell Iox with, in particular, Vcapa=(1/Cread)*§Iox. This voltage Vcapa, here injected into the non-inverting input of the comparator 120 is compared to a threshold Vref in order to distinguish a case in which the current Iox is at a level corresponding to a current Ilimit when the selector 330 is on and a case in which the current Iox is at a level corresponding to a current IoffOTS when the selector 330 is off.

Due to the regulation stage 101, during a sub-step of current reading at a voltage Vread, the conductive element BL connected to the cell 30 is maintained at a potentiel in the order of the read voltage Vread despite the voltage variation Vcapa across the read capacitor Cread. Here again, such an arrangement facilitates the implementation of a sequence of read voltages Vread1, Vread2, Vread3, at different levels from one another during successive sub-steps of a read operation. A reset to zero transistor Maz whose gate is controlled by a reset to zero signal Raz makes it possible to discharge the capacitor Cread between two current reading sub-steps at distinct read voltage levels.

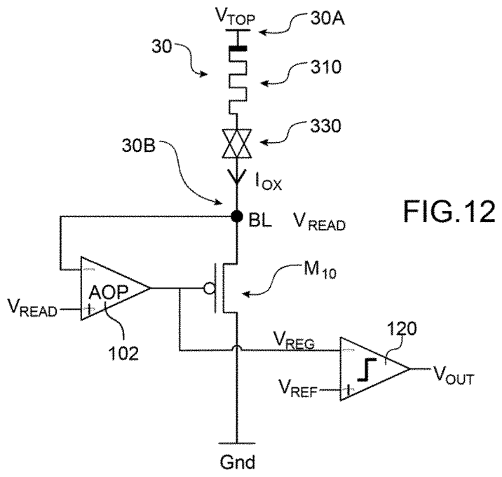

According to another variant illustrated in FIG. 12, the result of reading a current circulating in the cell following the application of a voltage Vread=Vread1 or Vread2 or Vread3 is always produced at the output of a comparator 120 producing the binary output signal Vout. In order to perform the comparison with respect to the voltage threshold Vref, this time a voltage Vreg is used at the output of the amplifier 102 of the regulation stage 101.

There is typically a difference of at least two decades between a current in the on state of the selector 330 and a current in the off state of the selector 330. Because of this difference, an output Vreg of the amplifier 102 of the control stage 101 gives an image of the current I_{OX} passing through the cell and therefore of the on or off state of the selector. indeed, when f_{OX} is at a “low” level corresponding to an off state of the selector 330, the V_{REG} output is at a high level so that the Vout output of the comparator 120 is at a level corresponding for example to a logic ‘0’. When the I_{OX} current is at a “high” level, V_{REG} will be relatively low allowing the Vout output of the comparator 120 to switch to an opposite logic level and corresponding to for example to a logic Y.

Alternatively, it is also possible to implement a regulation at the end 30A of the cell in this example set at a fixed potential Vtop, in order to be able to vary this potential VTOP from one read sub-step to the other.

Multi-level programming of a memory cell can be achieved in different ways. Programming current pulse make it possible to use the device as a memory. A so-called RESET pulse is a programming pules for bringing the device into a high-resistivity programming state HRS by applying a corresponding threshold voltage VthRESET.

According to a first configuration, the device is already in an HRS programming state.

In this case, for a change of threshold voltage to for example VthSET1 or VthSET2, . . . it is necessary that a sufficient programming current flows through the cell. The programming current is in the form of a pulse of very short duration and a combination of the presence of a significant programming current and an appropriate choice of large ramp-down duration of the pulse makes it possible to change the threshold voltage of the cell.

A “very short” duration is typically between 10 ns and 1 μs, for example 100 ns. A “significant” programming current typically means between 50 μA and 350 μA. A “significant” ramp down is typically 10 times less than the pulse duration for example 10 ns ramp down for a pulse duration of 100 ns.

Two different methods can be used to adjust the threshold voltage Vth of a 1S-1R cell.

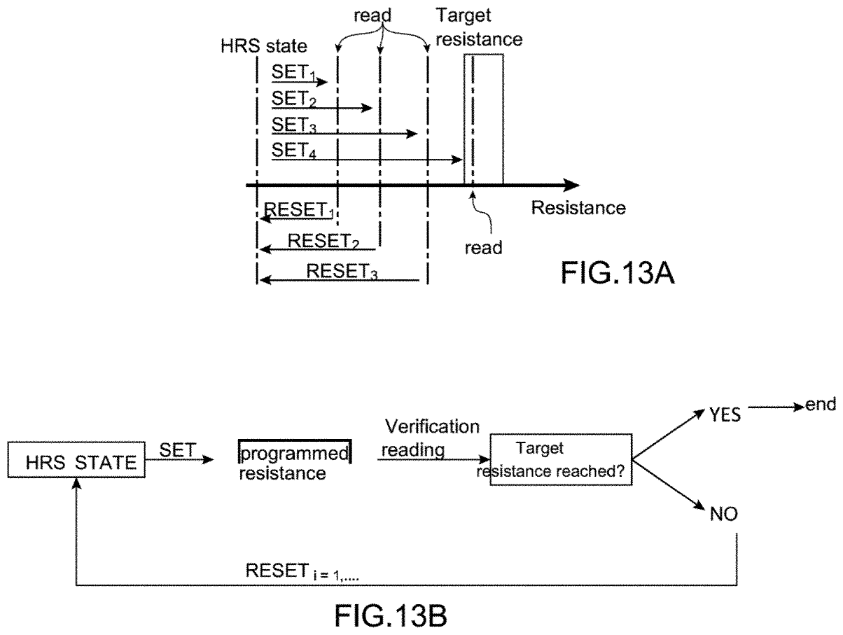

According to a first method illustrated in the diagram in FIG. 13A and the flowchart in FIG. 13B, a first current pulse SET₁ is sent to program the cell resistance. A verification reading is then made. If this verification reading detects that the target resistance has been reached, the programming is complete. If not, a RESET₁ pulse is applied to put the cell in a HRS state. This is then repeated with a SET₂ current pulse of higher intensity than the first SET pulse.

The SET current pulse is typically of opposite polarity than that of the RESET type for erasure.

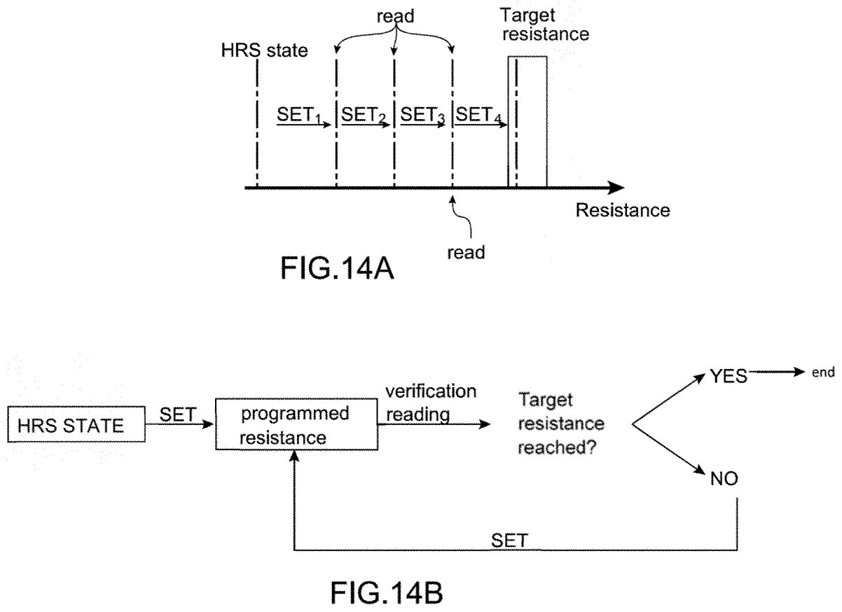

According to a second method illustrated in FIGS. 14A and 14B, a first current pulse current SET₁ is issued to program the cell resistance. A verification reading is then taken. If this verification reading indicates that the target resistance has been reached, the programming is complete. In the opposite case, a new SET₂ programming puke is applied, the intensity of which can be this time the same or possibly lower than the first SET₁ pulse.

Alternatively, rather than programming a memory cell with different levels of SET programming pulses to adjust the threshold voltage Vth, erasures can be carried out at different RESET voltage levels. In this way it is possible to modulate the typically negative RESET voltage applied at the terminals of the cell, which controls the cell resistance, the higher this voltage, the more cell will be erased and the higher the associated resistance will be.

In addition to their non-volatile character, the resistive memories can have a high integration density which makes them candidates for the implementation of neuro-morphic circuits formed by a set of artificial neurons. Such circuits can be used in fields such as for example signal processing, data classification, image recognition. A method of controlling resistive memory cells according to the invention can therefore also be applied to such neuromorphic circuits with resistive synapses and programmable for a number of more than two distinct programming states.

1. A memory device formed by resistive memory cells each provided with a resistive memory element associated in series with a selector, each cell implementing a multi-level coding and being programmed to a given programming state among k with k>2 possible programming states,
the device comprising a read circuit configured, during a read operation on a given cell: to apply a sequence of at least two successive and different read voltages to the given cell,
the read circuit being configured such that said sequence comprises the application of a first read voltage to the given cell, the first read voltage belonging to a first range of voltages between a first threshold voltage and a second threshold voltage, and being selected from a set of read voltages of a sequence different read voltages to which a cell of said memory is likely to be subjected during said read operation, then the application of a second read voltage of said sequence of read voltages, the second read voltage being different from the first read voltage and belonging to a second range of voltages between the second threshold voltage and a third threshold voltage, the given programming state being determined as a function of respective values of a first read current passing through said given cell resulting from the application of said first read voltage and a second read current passing through said given cell following the application of said second read voltage, the read circuit being further configured to detect at each applied read voltage of said sequence whether a read current passing through said given cell and resulting from the application of said read voltage corresponds to a first leakage current level of the selector when this selector is in an OFF state or whether the read current corresponds to a second current level when the selector is in an ON state.

2. The memory device according to claim 1, wherein during said read operation the sequence of different read voltages is applied by said read circuit to said given memory cell according to an increasing order of read voltages or according to a decreasing order of read voltages.

3. The memory device according to claim 1, wherein the selector is a switch with two terminals, in particular an ovonic threshold switch OTS.

4. The memory device according to claim 1, wherein the resistive memory element is an oxide-based resistive memory element OxRAM.

5. The memory device according to claim 1, the read circuit being provided with an amplifier having a non-inverting input to which the read voltage is applied and an inverting input connected to the drain of a transistor mounted in a common drain and coupled to the output of the selector.

6. The memory device according to claim 1, wherein the read circuit is configured to compare an image current from a first current mirror receiving a current from the selector to another current from a second current mirror to which a reference current is applied.

7. The memory device according to claim 1, wherein the read circuit is provided with a comparator for comparing a voltage at the output of the amplifier with a reference voltage.

8. The memory device according to claim 1, wherein the read circuit is provided with an integration capacity charged by an image current of a current from the selector, the read circuit being configured to discharge the integration capacity during the read operation according to said sequence of voltages following the application of a first read voltage of said sequence and prior to the application of a second read voltage following said first read voltage in said sequence of voltages.

9. A control method of a device according to claim 1, comprising during the read operation of a given programming state a given resistance memory cell among said resistive memory cells, steps consisting of:
applying a first read voltage to the given cell, the first read voltage belonging to a first range of voltages between a first threshold voltage and a second threshold voltage, and being selected from a set of read voltages of a sequence of different read voltages to which a cell of said memory is likely to be subjected during said read operation, then
applying a second read voltage, of said sequence of read voltages, the second read voltage being different from the first read voltage and belonging to a second voltage range between the second threshold voltage and a third threshold voltage, the given programming state being determined as a function of respective values of a first read current passing through said given cell resulting from the application of said first read voltage and a second read current traversing said given cell following the application of said second read voltage,
or,
triggering the end of the read operation:
when the first read voltage is the highest voltage of said sequence of voltages and the first current traversing said given cell and following the application of said first read voltage corresponds to a leakage current level of the selector when this selector is in an off state, or
when the first read voltage is the lowest voltage of said sequence of voltages and the first current corresponds to a current level when the selector is in an on state.

10. The control method according to claim 9, wherein the read operation further comprises, after applying the second read voltage:
a step of determining said given programming state as a function of the value of a sum between said first read current and said second read current.

11. The control method according to claim 9, further comprising, after applying the first read voltage and prior to the application of the second read voltage or triggering the end of the read operation:
a binary detection step consisting of determining whether the first read current corresponds to a leakage current level of the selector when this selector is in an off state or whether the first current corresponds to a current level when the selector is in an on state, in particular by comparing the first read current or an image of the first read current as a voltage or a current to a given threshold.

12. The control method according to claim 9, wherein the read operation further comprises after the step consisting of applying the second read voltage:
applying a third read voltage, of said sequence of read voltages, the third read voltage being different from said first read voltage and second read voltage and belonging to a third range of voltages between the third threshold voltage and a fourth threshold voltage, or
triggering the end of the read operation:
when the second read voltage is, apart from the first read voltage, the highest voltage of said sequence of voltages and the second read current corresponds to a leakage current level of the selector when this selector is in an off state, or
when the second read voltage is, apart from the first read voltage, the lowest voltage of said sequence of voltages and the second read current corresponds to a current level of the selector when the selector is in an on state.

13. The control method according to claim 12, wherein the read operation further comprises, after applying the third read voltage:
a step of determining said given programming state as a function of the value of a sum between said first read current, said second read current, and a third current passing through said given cell consecutive to the application of said third read voltage.

14. The control method according to claim 12, further comprising, after applying the second read voltage and prior to the application of the third read voltage or the triggering of the end of the read operation, a binary detection step consisting of determining whether the second read current corresponds to a leakage current level (IoffOTS) of the selector (33) when this selector is in an off state or if the second current corresponds to a current level (Ilimit) when the selector is in an on state.

15. The control method according to claim 9, wherein prior to the read operation, the programming of the given state is performed by applying a succession of current pulses to the given cell.
